(19) United States
(12) Patent Application Publication
(10) Pub. No.: US 2004/0245917 A1
(43) Pub. Date: Dec. 9, 2004

(54) Light-emitting devices with an embedded charge injection electrode

(76) Inventors: Zheng-Hong Lu, Toronto (CA); Xiaodong Feng, Toronto (CA)

Correspondence Address: Ralph A. Dowell of DOWELL & DOWELL, P.C., Suite 309, 1215 Jefferson Davis Highway, Arlington, VA, 22202, US

(21) Appl. No.: 10/828,549

(22) Filed: Apr. 21, 2004

Related U.S. Application Data
(60) Provisional application No. 60/464,662, filed on Apr. 23, 2003.

(51) Int. Cl. H05B 33/14; H05B 33/26

(52) U.S. Cl. 313/503; 313/504; 428/690

(57) ABSTRACT

The present invention provides an organic light-emitting device (OLED) is comprised of: (a) a cathode for external negative bias lead; (b) an anode for external positive bias lead; (c) an embedded charge injection electrode (ECIE) between the aforementioned cathode and anode; (d) an active region emitting light between the cathode and the anode. The ECIE is selected from low work function elements including Ca, Mg, Al, Ag, Au, Ni, Fe, Ni, and Co, bilayers including Fluorides/Al, Mg/Ag, Ca/Al, and trilayers of Fluorides/Al/Fluorides, Fluorides/Al/(Ca, Mg). The light-emitting layer is elected from conjugated small organic molecules and polymers. The anode is selected based from known high work function materials including ITO, SnO2, Ni, Pt, Au, p++ semiconductors (c-Si, a-Si, a-Si:H, poly silicon). The cathode is selected from one or more layers of high electrical conductive metals and alloys such as ITO, Al, Cr, Cu, Ag, Au, Ni, Fe, Ni, W, Mo and Co. The embedded charge injection electrode may be used as an optical interference layer, and the electron transport layer, hole transport or light emission layer as spacers depending on the location of the ICIE. Destructive optical interference from the embedded charge injection electrode and the reflective cathode or anode reduces ambient-light reflection.

### CROSS REFERENCE TO RELATED U.S APPLICATION

This patent application relates to, and claims the priority benefit from, U.S. Provisional Patent Application Ser. No. 60/464,662 filed on Apr. 23, 2003, which is incorporated herein by reference in its entirety.

### FIELD OF THE INVENTION

The present invention relates to organic-based light-emitting devices (OLEDs), and more particularly the invention relates to light-emitting devices with an embedded charge injection electrode.

### BACKGROUND OF THE INVENTION

A typical organic light-emitting device (OLED) includes an anode, an active light-emitting zone comprising one or more electroluminescent organic maiterial(s), and a cathode. One of the electrodes is optically transmissive which is the viewing side of the device while the other one is optically reflective. The function of the anode is to inject positively charged particles referred to as holes into the light-emitting zone, and that of the cathode is to inject electrons into the emission zone. A process involved in the recombination of electrons and holes is the production of light which is emitted from the recombination zone. The light wave is emitted through the aforementioned optically transmissive electrode.

U.S. Pat. No. 4,356,429 issued to CW Tang discloses inserting a hole transport layer between the anode and the emission zone, and an electron transport layer between the cathode and the emission zone. It is well documented that certain organic molecules are excellent for the transport of holes but very poor for the transport of electrons. It is critical to have balanced electron and hole density in the emission zone to obtain optimal device performance (see, for example, Aziz et al, “Degradation Mechanism of Small Molecule-Based Organic Light-Emitting Devices” Science, 283, 1900 (1999)). In order to enhance the electron injection, low work function metals such as Ca and Mg, which provides excellent energy band-matching to that of the lowest unoccupied molecular orbital (LUMO), has been selected as cathode materials. However, the low work function metals are highly reactive that leads to fragmentation of the organic molecules when vapour phase metal atoms strike on the organic film surface (see A. Turak et al “Metal/AIQ3 interface structures”, Appl. Phys. Left. V81 (n4), 766 (2002)). This limits the ability to use low work function metals as the cathode material.

Another problem of the cathode relates to the poor grain structure of metal films formed by thermal evaporation at low substrate temperature (<100oC) (M. Wu, “Metallic Thin Film Growth on Organic Surface”, B.Sc. Thesis, University of Toronto, April 2003). The light-emitting device stability suffers from the interface oxides formation between the cathode and the organic layer. The oxides formation is caused by a reaction between the cathode metal atoms and the ambient oxidant gases such as oxygen and water molecules which diffuse through the cathode via pin holes and grain boundaries, (see X. D. Feng, et al, “Studies of Alq/Mg: Ag Interface in Organic Light-Emitting Diodes by XPS”, MRS Proceedings V 725, 31 (2002)). The oxidized area blocks the electron injection pathway from the cathode.

This, combined with poor lateral electron conductivity of the organic materials, leads to the formation of dead emission zone (see, for example, H. Aziz et al “Humidity-induced crystallization of tris Ñ8-hydroxyquinoline aluminum layers in organic light-emitting devices”, Appl. Phys. Lett. 72 (n7), 756 (1998)).

Sputter deposition of pure materials or oxides, sulfides etc. is known to yield uniform films. However, the energetic species produced in the plasma during the sputtering process is well known to induce damage to the cathode/organic interface when sputter depositing a conductive layer, such as a metal or conductive transparent metal oxide such as indium tin oxide (ITO). This leads to the formation of the aforementioned dead emission zone and may even lead to a complete failure of the device (see for example S. Han et al, “Transparent-cathode for top-emission organic light-emitting diodes”, Appl. Phys. Lett. V82 (n16), 2715 (2003)).

If the ambient illumination is very high, a substantial amount of the ambient light is reflected by the reflective electrode, thereby it degrades the visually perceived contrast of the emitted light through the transparent electrode. It is quite important that an OLED device can be easily viewed under all the ambient illumination conditions (e.g. full sunlight).

Top-emitting organic light-emitting diodes are of great importance for the integration of OLED devices with electrical drivers. It is desirable for active-matrix OLED displays because all circuitry can be placed at the bottom without any interference from components such as wiring and transistors. However, both fabrication efficiency (time and yield) and device performance of top-emitting OLED devices are adversely affected by ITO sputtering.

### SUMMARY OF THE INVENTION

It is the object of the present invention to design a robust light-emitting device with a floating charge injection electrode embedded inside the device to permit: (a) the fabrication of a robust cathode from a wide variety of materials by effective thin-film deposition process including thermal evaporation, sputtering and PECVD (plasma-enhanced chemical vapour deposition); (b) a wider selection of robust electron-conductive molecules with a better energy band matching to the LUMO of the emissive organics through embedded electrode.

It is another object of the present invention to use the embedded charge injection electrode as an optical interference layer, and the electron transport layer, hole transport or light emission layer as spacers. Destructive optical interference from the embedded charge injection electrode and the reflective cathode or anode reduces ambient-light reflection.

In one aspect of the invention there is provided a light-emitting device having an embedded charge injection electrode, comprising:

a) a light-transmissive substrate;

b) a light-transmissive first electrode layer on the substrate;

c) a first charge transport layer on the first electrode layer for transporting charges injected from the first electrode layer into the first charge transport layer;

d) a light-emissive layer on the first charge transport layer;

e) a first charge injection electrode layer on the light-emissive layer with the charge injection electrode layer being electrically floating;

f) a second charge transport layer on the first charge injection electrode layer; and

g) a second electrode layer on the second charge transport layer wherein the second charge transport layer is for transporting charges injected from the second electrode layer.

In this aspect of the invention the first electrode layer is an anode electrode layer, wherein the second electrode layer is a cathode electrode layer, wherein the first charge transport layer is a hole transport layer, wherein the second charge transport layer is an organic-based electron transport layer, and wherein the first embedded charge injection electrode layer is formed of a low work function metal or metal alloy.

In another aspect of the invention there is provided a light-emitting device having an embedded charge injection electrode, comprising:

a) a substrate;

b) an optically reflective anode electrode layer on the substrate;

c) a hole-transport layer on the optically reflective anode electrode layer;

d) a light-emissive layer on the hole-transport layer;

e) a first charge injection electrode layer on the light-emissive layer with the charge injection electrode layer being electrically floating;

f) an organic electron-transport layer on the charge injection electrode layer; and

e) a light-transmissive cathode electrode layer on the organic electron-transport layer.

The present invention also provides a light-emitting device having an embedded charge injection electrode, comprising:

a) a light-transmissive substrate;

b) a light-transmissive anode electrode layer on the substrate;

c) a hole-transporting layer on the anode;

d) a first charge injection electrode layer on the hole-transporting layer with the charge injection electrode layer being electrically floating;

e) a light-emissive layer on the charge injection electrode layer;

f) an organic electron-transport layer on the light-emissive layer; and

g) a cathode electrode layer on the organic electron-transport layer.

The present invention also provides a light-emitting device having an embedded charge injection electrode, comprising:

a) a substrate;

b) an anode electrode layer on the substrate;

c) a hole-transporting layer on the anode;

d) a first charge injection electrode layer on the hole-transporting layer with the charge injection electrode being electrically floating;

e) a light-emissive layer on the charge injection electrode layer;

f) an organic electron-transport layer on the light-emissive layer; and

g) a transmissive cathode electrode layer on the organic electron-transport layer.

### BRIEF DESCRIPTION OF THE DRAWINGS

The light-emitting device produced according to the present invention will now be described, by way of example only, reference being made to the accompanying drawings, in which:

FIG. 1 is a schematic cross sectional view of a light-emitting device with an embedded charge injection electrode (ECIE) constructed in accordance with the present invention;

FIG. 2A shows the current-voltage characteristics of a light-emitting device without ECIE (shown in solid circles) and a light-emitting device with ECIE (shown in solid squares) as shown in FIG. 1;

FIG. 2B shows the luminance-voltage characteristics of a light-emitting device without ECIE (shown in solid circles) and a light-emitting device with ECIE (shown in solid squares) as shown in FIG. 1;

FIG. 3A shows the current-voltage characteristics of light-emitting devices with ECIE which use LiF/Al bi-layers as cathode (shown in solid squares) and a Ag layer as cathode (shown in solid circles);

FIG. 3B shows the luminance-voltage characteristics of light-emitting devices with ECIE which use LiF/Al bi-layers as cathode (shown in solid squares) and a Ag layer-as cathode (shown in solid circles);

FIG. 4A shows the current-voltage characteristics of light-emitting devices with ECIE which use Alq, C60 and CuPc as electron transport layers (ETLs), and Li/Al as cathodes;

FIG. 4B shows the luminance-voltage characteristics of light-emitting devices with ECIE which use Alq, C60 and CuPc as ETLs, and Li/Al as cathodes;

FIG. 5A shows the current-voltage characteristics of light-emitting devices with ECIE which uses CuPc as ETL and Ag as cathode materials;

FIG. 5B shows the luminance-voltage characteristics of light-emitting devices with embedded charge injection electrodes (ECIE) which uses CuPc as ETLs and Ag as cathode materials;

FIG. 6A shows in graphic optical reflectance-wavelength characteristics from an organic EL device with ECIL and a regular organic electroluminescence (EL) device;

FIG. 6B shows a photograph of EL devices with ECIE (the dark section on top left) and regular EL device (the shining section on the bottom right);

FIG. 7A shows in graphic form of current-voltage characteristics of an organic EL device with ECIL which includes a thin metal cathode and 100 nm ITO layer deposited by sputtering, the metal cathode is 20 nm thick Al and Ag, respectively;

FIG. 7B shows an optical transmission spectral from a stack of ECIE/Alq/Cathode;

FIG. 8 shows the current-voltage characteristics of a device with a structure: Substrate/Al(50 nm)/Alq(80 nm)/LiF(0.5 nm)/[embeded Al Layer (x nm)]/Alq(80 nm)/LiF(0.5 nm)/Al(100 nm) in which the embedded Al thickness, x, was varied to test the device performance, the data clearly showing that an embedded floating electrode will lower the operating voltage;

FIG. 9 shows a schematic cross sectional view of an alternative embodiment of a light-emitting device with an embedded charge injection electrode (ECIE) located between the hole transport layer and the EL layer; and

FIG. 10 shows L-J-V characteristics of the 1×2 mm² OLED devices with various ECIL-organic ETL-Cathode structures as labelled. The reference OLEDs with conventional one-layer cathodes are labelled as “Control 1” having a conventional OLED structure: ITO/TPD(60 nm)/Alq(68 nm)/LiF/Al(100 nm), and as “Control 2” having a conventional structure: ITO/TPD(60 nm)/Alq(148 nm)/LiF/Al(100 nm).

### DETAILED DESCRIPTION OF THE EMBODIMENTS

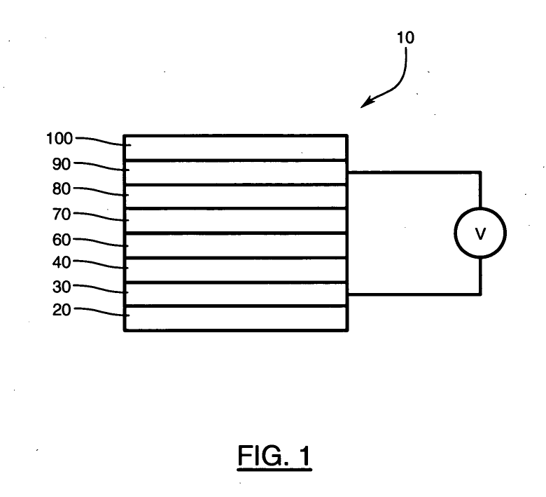

This invention in embodiments provides OLED devices comprising an embedded charge injection electrode (ECIE) embedded in the organic charge-transporting region. This invention in embodiments also provides methods for forming this OLED device. An OLED device 10 comprising an exemplary embodiment is shown in FIG. 1. The OLED device 10 is formed over a substrate 20, which is shown at the bottom for illustration only. The OLED device 10 comprises an anode 30, a hole-transporting layer 40, an active light-emission layer 60, an embedded charge injection electrode (ECIE) 70 on top of light-emission layer 60, an organic electron-transport layer 80 on ECIE layer 70, and a cathode 90 on layer 80. The anode 30 is selected from high work function conducting materials including indium tin oxide (ITO), SnO₂, Ni, Pt, Au, p++ semiconductors (c-Si, a-Si, a-Si:H, poly-silicon). Additional forms of anode are disclosed in U.S. Pat. No. 4,885,211 incorporated herein in its entirety.

The hole-transport layer 40 may be comprised of those materials disclosed in United States Patent application 20020180349 which is Ser. No. 10/117,812 published Dec. 5, 2002 which is incorporated herein by reference in its entirety which discloses different hole transport layer materials, electron transport layer materials, anode materials and cathode materials, which application refers to U.S. Pat. Nos. 4,539,507, 5,942,340 and 5,952,115 which are all incorporated herein by reference in their entirety.

The active light-emission layer 60 region can include any one or a mixture of two or more of fluorescent and phosphorescent materials including small molecules and polymers. For example, the active light-emission layer 60 may be comprised of those materials disclosed in United States Patent application 20020180349 which is Ser. No. 10/117,812 published Dec. 5, 2002 which is incorporated herein by reference in its entirety, which application refers to U.S. Pat. Nos. 4,539,507; 5,151,629; 5,150,006; 5,141,671 and 5,846,666 which are all incorporated herein by reference in their entirety. U.S. application Ser. Nos. 08/829,398; 09/489,144 and U.S. Pat. No. 6,057,048 also disclose materials which may be used in the present invention.

The cathode 90 is selected from one or more layers of high electrical conductive metals and alloys such as ITO, Al, Cr, Cu, Ag, Au, Ni, Fe, Ni, W, Mo and Co. An optional cathode capping layer 100 made of dielectrics, such as Si oxides and nitrides, may be deposited on the cathode by sputtering.

In some embodiments, the embedded charge injection electrode 70 may consist of LiF/Al bi-layers for efficient electron injection as described by Hung et al. in U.S. Pat. No. 5,776,622. Other suitable metals that can be used in the embedded charge injection electrode 70 may include, but are not limited to, Al, Mg, Ag, Ca, and mixtures thereof. The thickness of embedded charge injection electrode can range from 2 nm to 30 nm.

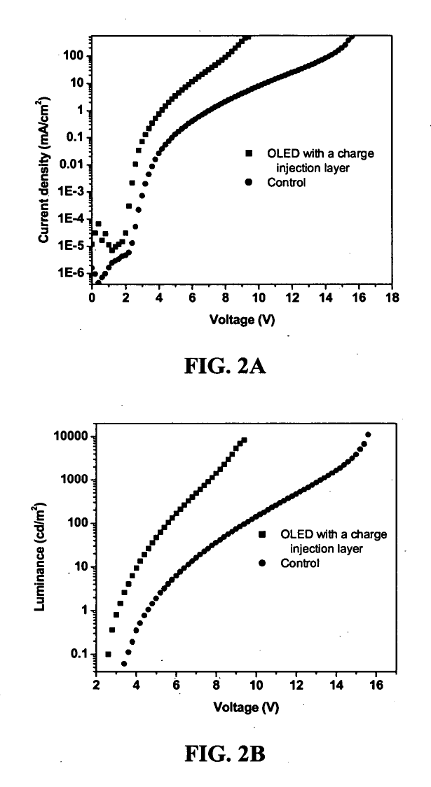

The insertion of an embedded charge injection electrode (ECIE) in OLEDs greatly improves current density-voltage (I-V) and luminance-voltage (L-V) characteristics, as shown by the results in FIGS. 2A and 2B. FIG. 2A shows current-voltage characteristics of a light-emitting device without ECIE (shown in solid circles) and a light-emitting device with ECIE (shown in solid squares) as shown in FIG. 1 in accordance with the present invention. FIG. 2B shows luminance-voltage characteristics of a light-emitting device without ECIE (shown in solid circles) and a light-emitting device with ECIE (shown in solid squares) as shown in FIG. 1.

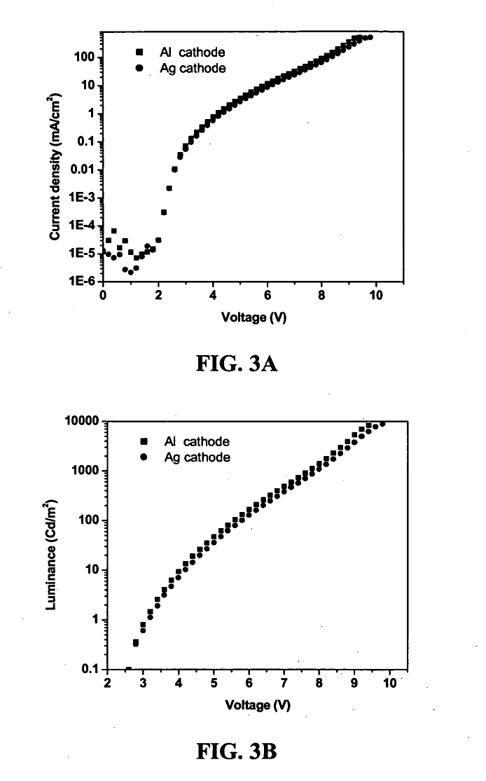

In both test devices, the electron transport layer (ETL) was Alq and had a thickness of 80 nm. The ECIE can provide a better engineering capability for production of OLEDs. FIG. 3A shows the current-voltage characteristics of light-emitting devices with ECIE which uses LiF/Al bi-layers as cathode and an Ag layer as cathode. FIG. 3B shows the luminance-voltage characteristics of light-emitting devices with ECIE which use LiF/Al bi-layers as cathode and an Ag layer as cathode. The device performance of conventional OLEDs is sensitive to the work function of cathode materials. (see, e.g. “Electron injection and transport in 8-hydroxyquinoline aluminum” Stöβel et. al. Synthetic Metals Volume 111-112, p.19). Since the injection of electrons determined by the ECIE interface, the performance of device 10 is not affected by the cathode materials. It is tremendously technical advantage to use a variety of stable conductive materials as cathode for better device protection without sacrificing the luminescence-current-voltage (L-I-V) characteristics of OLED devices.

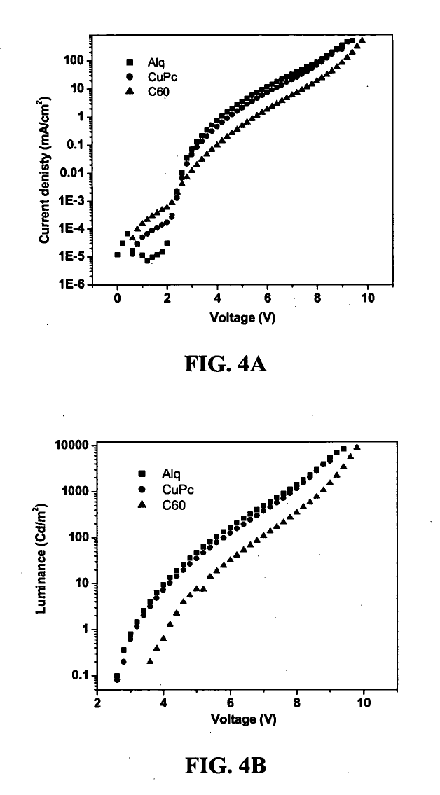

This invention can also permit a wide choice of electron transport layer 80. FIG. 4A shows the current-voltage characteristics of light-emitting devices with an ECIE which use Alq, C60 and CuPc as ETLs, and Li/Al as cathodes and FIG. 4B shows the luminance-voltage characteristics of light-emitting devices with ECIE which use Alq, C60 and CuPc as ETLs, and Li/Al as cathodes. Suitable electron conductive organic materials include, but are not limited to, tris-(8-hydroxyquinoline) aluminum (Alq), CuPc, C60, C70 and BCP. For example, the electron transport layer 80 may be comprised of those materials disclosed in United States Patent application 20020180349 which is Ser. No. 10/117,812 published Dec. 5, 2002 which is incorporated herein by reference in its entirety. The luminescent region may also comprise one or more materials with electron transporting properties. Specific example of electron transporting materials that may be used in the luminescent region are polyfluorenes, such as poly(9,9-di-n-octylfluorene-2,7-diyl), poly(2,8-(6,7,12,12-tetraalkylindenofluorene) and copolymers containing fluorenes such as fluorene-amine copolymers, as disclosed in Bemius et al., Proceedings of SPIE Conference on Organic Light Emitting materials and Devices III, Denver, Colo., July 1999, Volume 3797, p. 129. Other examples of electron transport materials that can be used are metal oxinoid compounds, oxadiazole metal chelate compounds, triazine compounds and stilbene compounds.

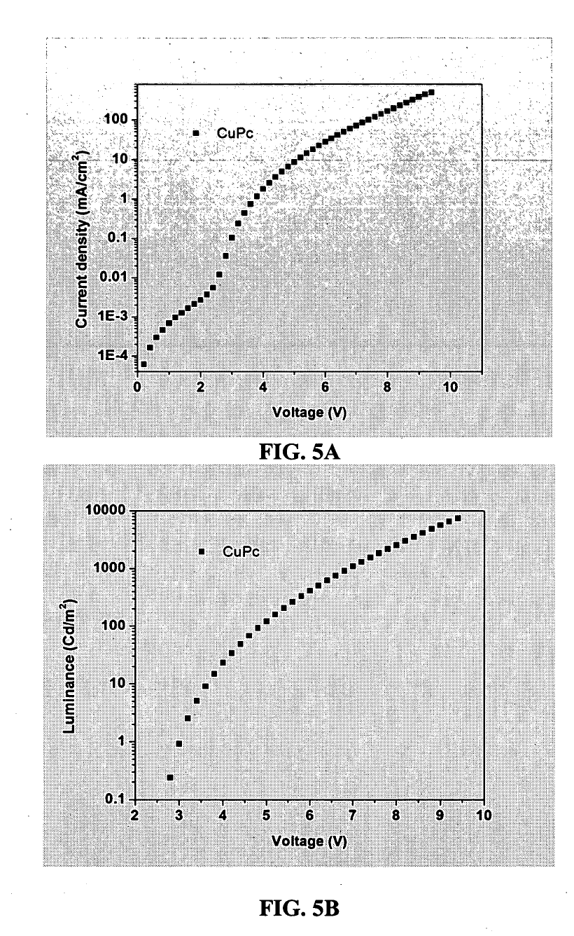

To further demonstrate the technical advantage of ECIE on manufacturing flexibility, FIG. 5A shows the current-voltage characteristics of light-emitting devices with an ECIE which use CuPc as ETLs and Ag as cathodes and FIG. 5B shows the luminance-voltage characteristics of the same light-emitting device. The FIGS. 4A to 5B clearly show a wide possible selection of ETL organics and cathode materials.

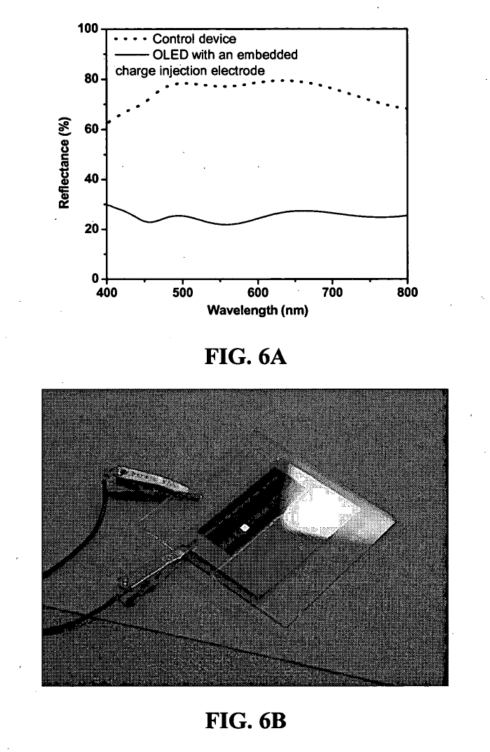

Proper choice of the thickness of ECIE and the electron-transporting layer 80 can provide destructive interference of environmental light, leading to high-contrast OLED devices. The principle of optical interference is the same as disclosed in U.S. Pat. No. 6,429,451 to Hung et al. and U.S. Pat. No. 6,411,019 to Hofstra et al. The reflectance of device 10 (according to this invention), and of conventional OLEDs at 7° relative to the normal direction was measured. The results, represented in the form of percentage of incident ambient light that is reflected back to the observer from the OLEDs, over the entire range of visible light are as shown in FIG. 6A. The visual imagine of aforementioned two devices as shown in FIG. 6B. (The dark section of device is the OLEDs with ECIE). Therefore, OLED devices including the ECIE according to this invention can be used in a wide range of OLED applications such as, for example, displays for televisions, computers, cellular phones and instruments.

In another embodiment of the invention the anode electrode may be reflective and the cathode may be light transmissive. Thus, the structure would comprise a substrate, an optically reflective anode electrode layer on the substrate, a hole-transport layer on the optically reflective anode electrode layer, a light-emissive layer on the hole-transport layer, a first charge injection electrode layer on the light-emissive layer with the charge injection electrode layer being electrically floating, an organic electron-transport layer on the charge injection electrode layer, and a light-transmissive cathode electrode layer on the organic electron-transport layer.

In this configuration, the thickness of the embedded charge injection electrode, the thickness of the hole-transport layer and the thickness of the light-emissive layer are selected to give destructive interference of pre-selected wavelengths of light.

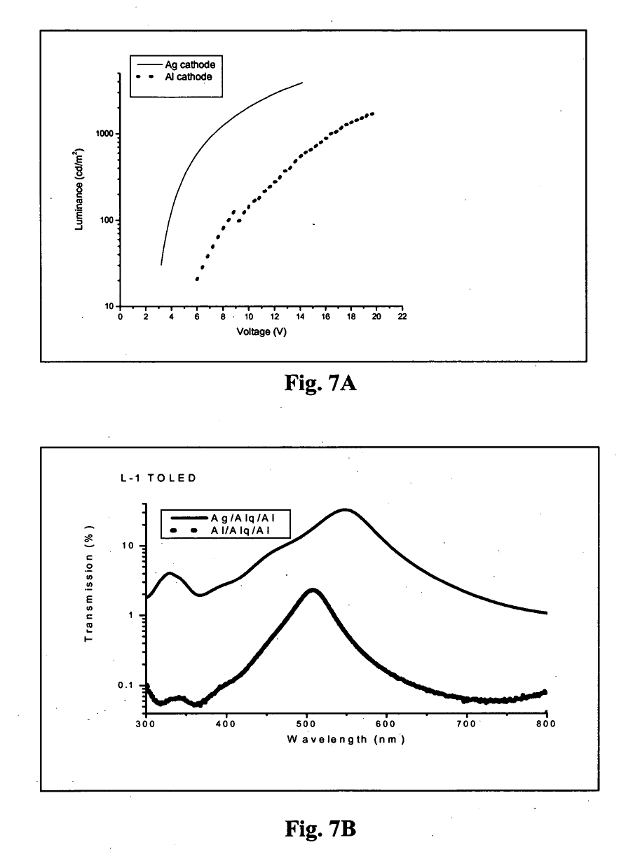

The ease of mass manufacturability of device 10 is attributed to the fact that the ECIE layer 70 is spaced farther away from cathode layer compared to prior art OLED devices. Deposition by sputtering on normal OLED's is not possible because of the damage induced at the cathode, interface by energetic plasma species (see S. Han et al, “Transparent-cathode for top-emission organic light-emitting diodes”, Appl. Phys. Lett. V82 (n16), 2715 (2003)). The advantage of OLED device 10 is that the cathode 90 functions only as electrical contact whereas the charge injection is through ECIE layer 70, of which the high lateral electrical conductivity redistributes the charge should any localized “dead” electrical spot develope at the interface between layer 80 and layer 90. The luminescence versus voltage data shown in FIG. 7A is for an OLED device where 20 nm thick Al or Ag cathode was deposited by thermal evaporation followed by sputter deposition of 100 nm ITO. FIG. 7A shows that use of high atomic number metals such as Ag is sufficient to limit the sputter damage not beyond ECIE. Here the ECIE is merely 3 nm thick.

Further functionality of the device 10 is that the both ECIE 70 and cathode 90 can be made of optically transmissive thin metal films so that light from EL layer 60 can escape through substrate 20 and cathode 90 creating double side visible EL device. Referring to FIG. 7A, the luminance-voltage recorded light output through layer 20. FIG. 7B shows the optical transmission spectra of stacked Ag/Alq/Al layers and Al/Alq/Al layers of identical ECIE/ETUCathode layers of the same test device shown in FIG. 7A.

Anode 30 of device 10 can be made of optically reflective materials, ECIE 70 and cathode 90 can be made of thin optically transmissive metals. This type of device is commonly referred to as top-emitting organic light device (TOLED).

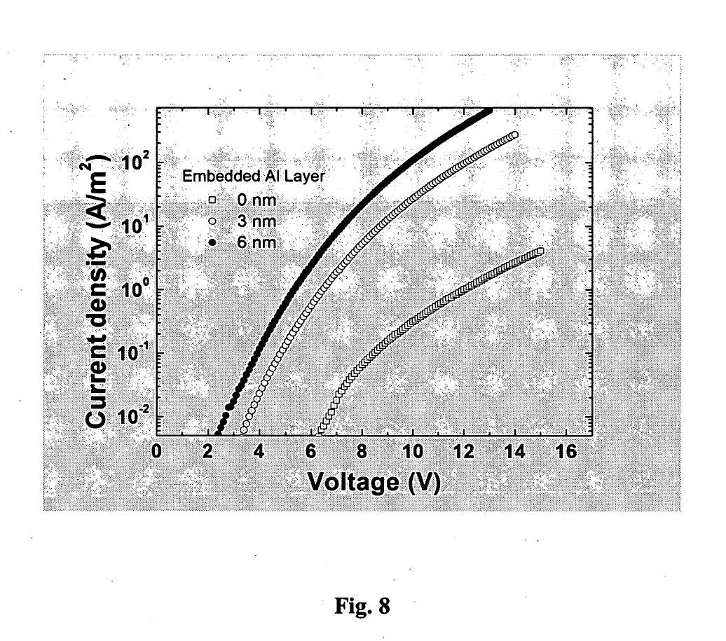

FIG. 8 shows the current-voltage characteristics of a device with a structure: Substrate/Al(50 nm)/Alq(80 nm)/LiF(0.5 nm)/[embeded Al Layer (x nm)]/Alq(80 nm)/LiF(0.5 nm)/Al(100 nm). The embedded Al thickness, x, was varied to test the device performance. The data clearly show that an embedded floating electrode will lower the operating voltage, which is a very significant and unexpected result.

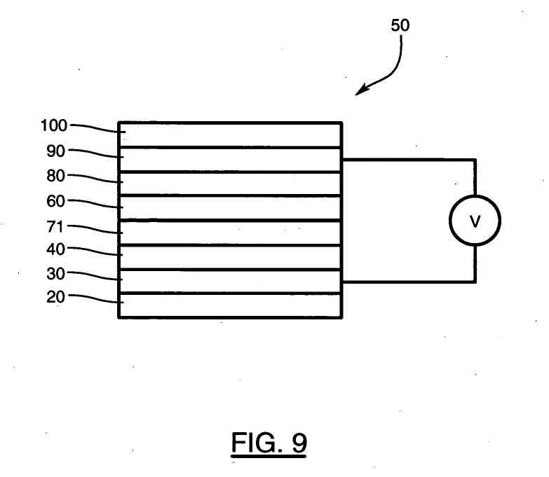

In another embodiment of the invention, the embedded charge injection electrode layer may be inserted between the hole transport layer 40 and the electroluminescent layer 60. Referring to FIG. 9, a display device 50 is shown in which an embedded charge injection electrode layer 71 is located between the hole transport layer 40 and the EL layer 60. This embedded charge injection electrode is formed of a high work function metal or metal oxide. For example, layer 71 may be made of the metal oxide indium tin oxide (ITO) or the metals capable of injecting holes. For example metals such as gold, Ni, platinum and silver are preferred.

In addition, the display devices may incorporate both the embedded charge injection electrode layer 70 between electron transport layer 80 and EL layer 60 in FIG. 1 and the embedded charge injection electrode layer 71 between hole transport layer 40 and EL layer 60 in FIG. 9.

When the embedded charge injection electrode 71 is located between hole transport layer 40 and EL layer 60 as shown in FIG. 9, to obtain destructive interference of unwanted wavelengths, the thickness of the first embedded charge injection electrode, the thickness of the light emissive layer and the thickness electron transport layer are selected to give destructive interference of pre-selected wavelengths of light.

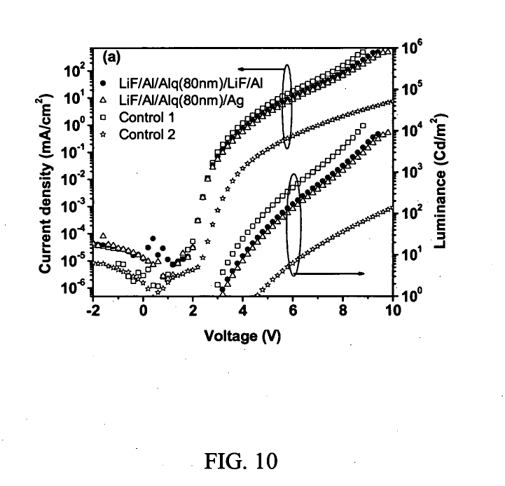

We now discuss the function of each constituent of the cathode 90/electron transport layer 80/embedded charge electrode 70 In order to examine whether the front thin metal mirror plays any role in the device operation OLEDs with different ECIE-ETL-cathode structures (also referred to as a metal-organic-metal (MOM) structures) and two “Control” devices were produced made. “Control 1” has a structure of ITO/TPD(60 nm)/Alq(68 nm)/LiF/Al(100 nm) and “Control 2” has a structure of ITO/TPD(60 nm)/Alq(148 nm)/LiF/Al(100 nm) which is simply an ECIE-ETL-cathode OLED without the ECIE. As shown in FIG. 10, the J-V characteristics of device with a MOM cathode is comparable to the device with a regular LiF/Al cathode (“Control 1”), while the current density is found to decrease dramatically if the ECIE is removed (“Control 2”). This indicates that the ECIE plays a critical role in charge injection process.

To further test this, a ECIE-organic ETL-cathode with the rear LiF/Al bi-layer cathode replaced by a Ag layer cathode which results in little change in the I-V characteristics as is shown in FIG. 10. To eliminate other physical causes such as electrical shorting between the ECIE and the cathode layer by percolated metal islands through the organic space layer, a device has been made using hole transporting TPD as the organic spacer between ECIE and cathode. The results show that the current density is 4 to 5 orders lower than that of other devices with electron transporting spacers and moreover there is no observable light output from such diodes. Although the precise device physics of the ECIE needs further theoretical investigation, it is quite clear that the ECIE functions as an embedded floating electron injection electrode whereas the rear metal electrode serves as an electrical contact to external circuit. From device physics point of view, the current device structure is actually a tri-electrode device with a floating electrode serving as an electron storage and injection, somewhat similar to a flash memory device. The difference here is that the organic spacer is semiconducting whereas the floating electrode 70 is separated by insulating layers in a flash memory device. Without being limited by any theory, it is quite possible that injection of electrons from both the front floating electrode and the rear electrode occurs simultaneously under a forward bias. The injection rates, however, may differ initially at these two interfaces. This will result in a built-in potential across the organic spacer. The built-in potential will eventually help establish a balanced electron flow between the ECIE and cathode.

As used herein, the terms “comprises”, “comprising”, “including” and “includes” are to be construed as being inclusive and open ended, and not exclusive. Specifically, when used in this specification including claims, the terms “comprises”, “comprising”, “including” and “includes” and variations thereof mean the specified features, steps or components are included. These terms are not to be interpreted to exclude the presence of other features, steps or components.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

Therefore what is claimed is:

1. A light-emitting device having an embedded charge injection electrode, comprising:
a) a light-transmissive substrate;
b) a light-transmissive first electrode layer on the substrate;
c) a first charge transport layer on the first electrode layer for transporting charges injected from the first electrode layer into the first charge transport layer;
d) a light-emissive layer on the first charge transport layer;
e) a first charge injection electrode layer on the light-emissive layer with the charge injection electrode layer being electrically floating;
f) a second charge transport layer on the first charge injection electrode layer; and
g) a second electrode layer on the second charge transport layer wherein the second charge transport layer is for transporting charges injected from the second electrode layer.

2. The light-emitting device of claim 1 wherein the first electrode layer is an anode electrode layer, wherein the second electrode layer is a cathode electrode layer, wherein the first charge transport layer is a hole transport layer, wherein the second charge transport layer is an organic-based electron transport layer, and wherein the first embedded charge injection electrode layer is formed of a low work function metal or metal alloy.

3. The light-emitting device of claim 2 wherein the first embedded charge injection electrode layer is formed of a material selected from the group consisting of Ag, Al, Ca, Mg and alloys of Mg:Ag.

4. The light-emitting device of claim 2 wherein the first embedded charge injection electrode layer is formed of one of a bi-layer of alkali fluoride/metal and a bi-layer of metal/metal.

5. The light-emitting device of claim 4 wherein the bi-layer of alkali fluoride/metal is LiF/Al.

6. The light-emitting device of claim 2 wherein the first embedded charge injection electrode is formed of tri-layer of one of an alkali fluoride/metal/alkaline fluoride or alkaline fluoride/metal/metal.

7. The light-emitting device of claim 6 wherein the tri-layer of an alkali fluoride/metal/alkali fluoride is LiF/Al/LiF and the tri-layer of a fluoride/metal/metal is LiF/Al/Mg.

8. The light-emitting device of claim 4 wherein the metal layers in the bilayers and trilayers have a thickness in a range from 2 nm to 30 nm.

9. The light-emitting devices of claim 4 wherein the alkali fluoride layer thickness is in a range from about 0.2 to 1.0 nm.

10. The light-emitting device of claim 2 wherein the organic electron-transport layer is formed of electron-conductive organic molecules.

11. The light-emitting device of claim 10 wherein the organic electron-transport layer has a thickness in a range from about 30 to about 300 nm.

12. The light-emitting device of claim 2 wherein the cathode electrode layer is made of a material selected from the group consisting of ITO, Al, Cr, Cu, Ag, Au, Ni, Fe, Ni, W, Mo and Co.

13. The light-emitting device of claim 2 wherein the anode electrode layer is made of a material selected from the group consisting of ITO, SnO₂, Ni, Pt, Au, p++ semiconductors (c-Si, a-Si, a-Si:H, poly silicon).

14. The light-emitting device of claim 2 including a cathode capping layer made of dielectrics on the cathode comprised of one of a Si oxide and a nitride.

15. The light-emitting device of claim 2 including a second charge injection electrode layer between the light-emissive layer and the hole transport layer with the second charge injection electrode being electrically floating.

16. The light-emitting device of claim 15 wherein the second embedded charge injection electrode layer is formed of a material selected from the group consisting of high work function metals and metal oxides.

17. The light-emitting device of claim 16 wherein the second embedded charge injection electrode layer is formed of a material selected from the group consisting of high work indium tin oxide (ITO), gold, nickel, platinum and silver.

18. The light-emitting device of claim 2 wherein the organic electron-transport layer is formed of electron-conductive organic molecules selected from the group consisting of Alq, fullerenes C60 and C70, CuPc and conducting aromatic compounds.

19. The light-emitting device of claim 1 wherein a thickness of the first embedded charge injection electrode and a thickness of the electron-transport layer are selected to give destructive interference of pre-selected wavelengths of light.

20. A light-emitting device having an embedded charge injection electrode, comprising:
a) a substrate;
b) an optically reflective anode electrode layer on the substrate;
c) a hole-transport layer on the optically reflective anode electrode layer;
d) a light-emissive layer on the hole-transport layer;
e) a first charge injection electrode layer on the light-emissive layer with the charge injection electrode layer being electrically floating;
f) an organic electron-transport layer on the charge injection electrode layer; and
e) a light-transmissive cathode electrode layer on the organic electron-transport layer.

21. The light-emitting device of claim 22 wherein the organic electron-transport layer is formed of electron-conductive molecules.

22. The light-emitting device of claim 21 wherein the organic electron-transport layer is selected from the group consisting of Alq, CuPc, fullerenes C60 and C70, and conducting aromatic compounds.

23. The light-emitting device of claim 22 wherein the organic electron-transport layer has a thickness in a range from about 30 to about 300 nm.

24. The light-emitting device of claim 20 wherein the first embedded charge injection electrode layer is made of a low work function metal or metal alloy.

25. The light-emitting device of claim 24 wherein the first embedded charge injection electrode layer is formed of a material selected from the group consisting of Ag, Al, Ca, Mg and alloys of Mg:Ag.

26. The light-emitting device of claim 20 wherein the first embedded charge injection electrode layer is formed of one of a bi-layer of alkali fluoride/metal and a bi-layer of metal/metal.

27. The light-emitting device of claim 26 wherein the brayer of alkali fluoride/metal is LiF/Al.

28. The light-emitting device of claim 20 wherein the first embedded charge injection electrode layer is formed of tri-layer of one of an alkali fluoride/metal/alkaline fluoride and an alkaline fluoride/metal/metal.

29. The light-emitting device of claim 28 wherein the tri-layer of an alkali fluoride/metal/alkali fluoride is LiF/Al/LiF and the tri-layer of a fluoride/metal/metal is LiF/Al/Mg.

30. The light-emitting device of claim 26 wherein the metal layers in the bilayers and trilayers have a thickness in a range from about 2 nm to about 30 nm.

31. The light-emitting device of claim 26 wherein the alkali fluoride layer thickness is in a range from about 0.2 to about 1.0 nm.

32. The light-emitting device of claim 20 wherein the cathode electrode layer is a metal, metal oxide or metal layer selected from the group consisting of Al, Cu, Ag, Mg:Ag, Au and ITO.

33. The light-emitting device of claim 32 wherein the alloy or metal layer has a thickness in a range from 15 nm to 300 nm.

34. The light-emitting device of claim 20 including a cathode capping layer made of dielectrics deposited on the cathode by sputtering comprised of one of a Si oxide and a nitride.

35. The light-emitting device of claim 20 wherein a thickness of the first embedded charge injection electrode and a thickness of the hole-transport layer and a thickness of the light-emissive layer are selected to give destructive interference of pre-selected wavelengths of light.

36. A light-emitting device having an embedded charge injection electrode, comprising:
a) a light-transmissive substrate;
b) a light-transmissive anode electrode layer on the substrate;
c) a hole-transporting layer on the anode;
d) a first charge injection electrode layer on the hole-transporting layer with the charge injection electrode being electrically floating;
e) a light-emissive layer on the charge injection electrode layer;
f) an organic electron-transport layer on the light-emissive layer; and
g) a cathode electrode layer on the organic electron-transport layer.

37. The light-emitting device of claim 36 including a second charge injection electrode layer between the light-emissive layer and the electron transport layer with the second charge injection electrode being electrically floating.

38. The light-emitting device of claim 36 wherein the first embedded charge injection electrode layer is formed of a material selected from the group consisting of high work function metals and metal oxides.

39. The light-emitting device of claim 36 wherein the first embedded charge injection electrode layer is formed of a material selected from the group consisting of high work indium tin oxide (ITO), gold, nickel, platinum and silver.

40. The light-emitting device of claim 39 wherein the first embedded charge injection electrode layer is formed of a material selected from the group consisting of graphitic carbon and nanostructured carbon fullerenes, C60 and C70.

41. The light-emitting device of claim 37 wherein the second embedded charge injection electrode layer is formed of low work function metals or metal alloys.

42. The light-emitting device of claim 41 wherein the second embedded charge injection electrode is formed of a material selected from the group consisting of Ag, Al, Ca, Mg and alloys of Mg:Ag.

43. The light-emitting device of claim 36 wherein the first embedded charge injection electrode is formed of one of a bi-layer of alkali fluoride/metal and bi-layer of metal/metal.

44. The light-emitting device of claim 43 wherein the bi-layer of alkali fluoride/metal is LiF/Al.

45. The light-emitting device of claim 36 wherein a thickness of the first embedded charge injection electrode and a thickness of the light emissive layer and the electron transport layer are selected to give destructive interference of pre-selected wavelengths of light.

46. A light-emitting device having an embedded charge injection electrode, comprising:
a) a substrate;
b) an anode electrode layer on the substrate;
c) a hole-transporting layer on the anode;
d) a first charge injection electrode layer on the hole-transporting layer with the charge injection electrode being electrically floating;
e) a light-emissive layer on the charge injection electrode layer;
f) an organic electron-transport layer on the light-emissive layer; and
g) a transmissive cathode electrode layer on the organic electron-transport layer.

47. The light-emitting device of claim 46 including a second charge injection electrode layer between the light-emissive layer and the electron transport layer with the second charge injection electrode being electrically floating.

48. The light-emitting device of claim 46 wherein the first embedded charge injection electrode is formed of a material selected from the group consisting of highly reflective metals.

49. The light-emitting device of claim 48 wherein the highly reflective metals are selected from the group consisting of Al and Cr.

50. The light-emitting device of claim 48 wherein the first embedded charge injection electrode layer is formed of a material selected from the group consisting of high work function metals and metal oxides.

51. The light-emitting device of claim 50 wherein the first embedded charge injection electrode is formed of a material selected from the group consisting of high work indium tin oxide (ITO), gold, nickel, platinum and silver.

52. The light-emitting device of claim 50 wherein the first embedded charge injection electrode is formed of a material selected from the group consisting of graphitic carbon and nanostructured carbon fullerenes, C60 and C70.

53. The light-emitting device of claim 47 wherein the second embedded charge injection electrode layer is formed of a low work function metal or metal alloy.

54. The light-emitting device of claim 53 wherein the second embedded charge injection electrode layer is formed of a material selected from the group consisting of Ag, Al, Ca, Mg and alloys of Mg:Ag.

55. The light-emitting device of claim 46 wherein the second embedded charge injection electrode is formed of one of a bi-layer of alkali fluoride/metal, and a bi-layer of metal/metal.

56. The light-emitting device of claim 55 wherein the bi-layer of alkali fluoride/metal is LiF/Al.

57. The light-emitting device of claim 46 wherein the first embedded charge injection electrode is formed of one of a tri-layer of an alkali fluoride/metal/alkali fluoride and a fluoride/metal/metal.

58. The light-emitting device of claim 57 wherein the tri-layer of an alkali fluoride/metal/alkali fluoride is LiF/Al/LiF and the tri-layer of a fluoride/metal/metal is LiF/Al/Mg.

59. The light-emitting device of claim 46 wherein a thickness of the first embedded charge injection electrode and a thickness of the hole-transport layer are selected to give destructive interference of pre-selected wavelengths of light.

60. The light-emitting device of claim 1 including a power supply means connected between the anode electrode layer and the cathode electrode layer for applying a pre-selected voltage across the anode electrode layer and the cathode electrode layer and all layers therebetween.

61. The light-emitting device of claim 1 wherein the light emissive layer is produced using any one of organic based fluorescent and phosphorescent molecules or polymers, and combinations thereof.
